(19) United States
(12) Patent Application Publication
(10) Pub. No.: US 2008/0029844 A1
(43) Pub. Date: Feb. 7, 2008

(54) ANTI-FUSE STRUCTURE OPTIONALLY INTEGRATED WITH GUARD RING STRUCTURE

(76) Inventors: James W. Adkisson, Jericho, VT (US); Jeffrey P. Gambino, Westford, VT (US); Kirk D. Peterson, Jericho, VT (US); William R. Tonti, Essex Junction, VT (US)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/462,070

(22) Filed: Aug. 3, 2006

(51) Int. Cl. H01L 29/00

(52) U.S. Cl. 257/530

(57) ABSTRACT

An anti-fuse structure and a related method for fabricating the anti-fuse structure include a doped well within a semiconductor substrate. A first aperture and a second aperture that expose the doped well are located within a dielectric layer located over the semiconductor substrate and the doped well. A first conductor layer is located within the first aperture and a second conductor layer is located within the second aperture. At least a first anti-fuse material layer contacts the first conductor layer. The first conductor layer and the second conductor layer may comprise doped conductor materials that upon fusing of the anti-fuse structure provide an anti-fuse diode or an anti-fuse resistor.

### BACKGROUND

1. Field of the Invention

The invention relates generally to anti-fuse structures and guard ring structures within semiconductor structures. More particularly, the invention relates to anti-fuse structures optionally integrated with guard ring structures within semiconductor structures.

2. Description of the Related Art

In addition to resistors, transistors, diodes and capacitors, semiconductor circuits also routinely include anti-fuse structures. Anti-fuse structures within semiconductor circuits are often used to interconnect redundant replacement circuit elements by enabling a latch when a particular defective circuit element is located. For example, anti-fuse structures are used for replacement of defective sub-arrays within memory arrays. Anti-fuse structures also have other applications within semiconductor circuits.

In addition to anti-fuse structures, semiconductor circuits also routinely include guard ring structures. Guard ring structures are used to encircle a chip, or area of circuitry within a chip, to protect the circuitry encircled within the guard ring structure from damage due to chip dicing or mobile ion ingress. In addition, guard ring structures may also be used to make electrical connection to a semiconductor substrate within a chip.

Various anti-fuse structures, and methods for fabrication thereof, are known in the semiconductor fabrication art.

Bertin et al., in U.S. Pat. No. 6,396,121, U.S. Pub. No. 2003/0132504 and U.S. Pub. No. 2005/0145983 teaches an anti-fuse structure that may be fabricated within a silicon-on-insulator (SOI) substrate. The anti-fuse structure penetrates into a base semiconductor substrate within the silicon-on-insulator (SOI) substrate and the anti-fuse structure also connects to a silicon surface layer within the silicon-on-insulator (SOI) substrate.

Marr et al., in U.S. Pat. No. 6,836,000 and U.S. Pub. No. 2005/0029622 teaches another anti-fuse structure that may be fabricated within a silicon-on-insulator (SOI) substrate. This particular anti-fuse structure is formed with respect to a doped well within the silicon-on-insulator (SOI) substrate.

Lin et al., in U.S. Pub. No. 2005/0110133 teaches an anti-fuse structure that has enhanced performance. To provide the enhanced performance, this particular anti-fuse structure includes a metal silicide layer that provides a lower resistance of the anti-fuse structure when fused.

Bergemont et al., in U.S. Pat. No. 6,362,023 teaches a dielectric anti-fuse cell and a method for fabrication of the dielectric anti-fuse cell that allows for an anti-fuse dielectric area to be scaled along with a thickness of the anti-fuse dielectric. This particular dielectric anti-fuse cell comprises an anti-fuse dielectric layer interposed between a polysilicon plug and a polysilicon layer.

Herner, in U.S. Pub. No. 20031/0173643 and U.S. Pub. No. 2005/0112804 teaches an anti-fuse structure with enhanced reliability. To achieve the enhanced reliability, this particular anti-fuse structure comprises a silicide layer, a grown silicon oxide anti-fuse layer upon the silicide layer and a semiconductor layer contacting the anti-fuse layer.

Knall in U.S. Pub. No. 2005/0026334, teaches a three-dimensional, field-programmable non-volatile memory that includes at least one anti-fuse. The at least one anti-fuse is configured as an anti-fuse diode within a self-aligned pillar that comprises the non-volatile memory.

Semiconductor structure dimensions are certain to continue to decrease, and to that end anti-fuse structures and guard ring structures are likely to continue to be of value within semiconductor structures. Thus, desirable but apparently absent within semiconductor structures and semiconductor circuit fabrication are anti-fuse structures and guard ring structures that may be efficiently integrated to allow for fabrication of those semiconductor structures and semiconductor circuits.

### SUMMARY OF THE INVENTION

The invention provides a semiconductor structure and a method for fabricating the semiconductor structure. The semiconductor structure includes an anti-fuse structure that may optionally be integrated with a guard ring structure.

A semiconductor structure in accordance with the invention includes a semiconductor substrate including a doped well, and a dielectric layer located covering the semiconductor substrate and the doped well. The semiconductor structure also includes at least a first aperture and a second aperture located within the dielectric layer, where each of the first aperture and the second aperture exposes the doped well. The semiconductor structure also includes a first conductor layer located within the first aperture and a second conductor layer located within the second aperture. The semiconductor structure also includes at least a first anti-fuse material layer contacting at least the first conductor layer.

Another semiconductor structure in accordance with the invention also includes a semiconductor substrate including a doped well and a dielectric layer located covering the semiconductor substrate and the doped well. This other semiconductor structure also includes at least a first aperture and a second aperture located within the dielectric layer, where each of the first aperture and the second aperture exposes the doped well. This other semiconductor structure also includes a first conductor layer located within the first aperture and a second conductor layer located within the second aperture. This other semiconductor structure also includes at least a first anti-fuse material layer contacting at least the first conductor layer. This other semiconductor structure also includes a guard ring structure electrically coupled to at least one of the first conductor layer and the second conductor layer.

A method for fabricating a semiconductor structure in accordance with the invention includes forming at least a first aperture and a second aperture located within a dielectric layer to expose a doped well located within a semiconductor substrate located beneath the dielectric layer. The method also includes forming a first conductor layer located within the first aperture and a second conductor layer located within the second aperture. Finally, the method also includes forming at least a first anti-fuse material layer contacting at least the first conductor layer.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, which form a material part of this disclosure, wherein:

FIG. 1 to FIG. 8 show a series of schematic cross-sectional diagrams illustrating the results of progressive stages in fabricating a plurality of semiconductor structures including anti-fuse structures in accordance with a plurality of embodiments of the invention.

FIG. 9 to FIG. 12 show a series of schematic cross-sectional diagrams illustrating the anti-fuse structures in accordance with the plurality of embodiments of the invention integrated with guard ring structures.

FIG. 13 shows a schematic plan-view diagram of a semiconductor structure including a guard ring structure.

FIG. 14 shows a schematic cross-sectional diagram of an additional semiconductor structure including an anti-fuse structure integrated with a guard ring structure.

### DESCRIPTION OF THE PREFERRED EMBODIMENTS

The invention, which includes an anti-fuse structure that may be integrated with a guard ring structure, and a method for fabricating the anti-fuse structure that may be integrated with the guard ring structure, is described in further detail within the context of the description provided below. The description provided below is understood within the context of the drawings described above. Since the drawings are intended for illustrative purposes, they are not necessarily drawn to scale.

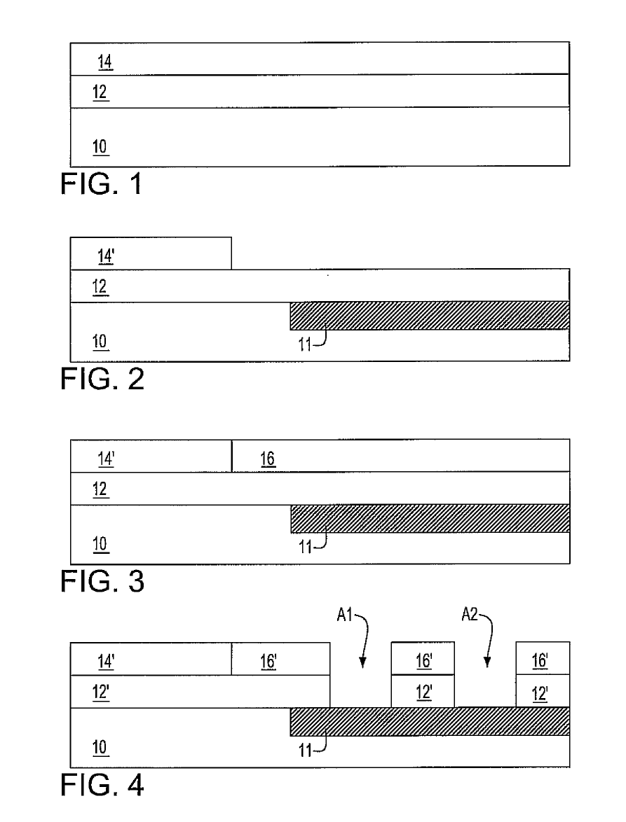

By reference to FIG. 1 to FIG. 8, shown is a series of schematic cross-sectional diagrams illustrating the results of progressive stages in fabricating a plurality of semiconductor structures in accordance with a plurality of embodiments of the invention. Shown in FIG. 1 is a schematic cross-sectional diagram of a semiconductor structure at an early stage in fabrication thereof in accordance with the preferred embodiments.

FIG. 1 shows a base semiconductor substrate 10. A buried dielectric layer 12 is located upon the base semiconductor substrate 10. A surface semiconductor layer 14 is located upon the buried dielectric layer 12.

Each of the foregoing semiconductor substrate 10, buried dielectric layer 12 and surface semiconductor layer 14 may comprise materials and have dimensions that are conventional in the semiconductor fabrication art. Each of the foregoing base semiconductor substrate 10, buried dielectric layer 12 and surface semiconductor layer 14 may be formed using methods that are conventional in the semiconductor fabrication art.

The base semiconductor substrate 10 comprises a semiconductor material. Non-limiting examples of semiconductor materials include silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials. Typically, the base semiconductor substrate 10 has a thickness from about 0.5 to about 1.5 mm.

The buried dielectric layer 12 comprises a dielectric material. Non-limiting examples of common dielectric materials from which may be comprised the buried dielectric layer 12 include oxides, nitrides and oxynitrides of silicon. Oxides, nitrides and oxynitrides of other elements are not excluded. The dielectric materials, which may be crystalline dielectric materials or amorphous dielectric materials, may be formed using any of several methods. Non-limiting examples include thermal or plasma oxidation or nitridation methods, chemical vapor deposition methods and physical vapor deposition methods. Typically, the buried dielectric layer 12 comprises at least in part a silicon oxide dielectric material that has a thickness from about 1000 to about 4000 angstroms, Alternatively, however, the buried dielectric layer 12 may be thinner in nature, for example 50 to 200 angstroms, or thinner.

The surface semiconductor layer 14 may comprise any of the several semiconductor materials from which is comprised the base semiconductor substrate 10. The surface semiconductor layer 14 and the base semiconductor substrate 10 may comprise the same semiconductor material or different semiconductor materials. The surface semiconductor layer 14 and the base semiconductor substrate 10 may also have the same crystallographic orientation or different crystallographic orientations. Typically, the surface semiconductor layer 14 has a thickness from about 300 to about 3000 angstroms.

As is understood by a person skilled in the art, the semiconductor structure that is illustrated in FIG. 1 (i.e., a layered structure comprising a base semiconductor substrate 10, a buried dielectric layer 12 located thereupon and a surface semiconductor layer 14 located further thereupon) comprises a semiconductor-on-insulator structure. The semiconductor-on-insulator structure may be fabricated using any of several methods. Non-limiting examples include layer transfer methods, lamination methods and separation by implantation of oxygen methods.

Although the preferred embodiments illustrate the invention within the context of a semiconductor-on-insulator structure that is illustrated in FIG. 1, the embodiments are not limited to only a semiconductor-on-insulator structure. Rather the invention may also be illustrated within the context of embodiments that use bulk semiconductor substrates and hybrid orientation substrates, in addition to semiconductor-on-insulator substrates. Hybrid orientation substrates comprise semiconductor substrates that include multiple crystallographic orientations.

FIG. 2 shows a surface semiconductor layer 14′ that results from patterning of the surface semiconductor layer 14 that is illustrated in FIG. 1. The surface semiconductor layer 14 may be patterned to form the surface semiconductor layer 14′ while using methods that are conventional in the semiconductor fabrication art. Included are photolithographic masking methods and etch methods that are generally known in the semiconductor fabrication art. The etch methods may include, but are not limited to wet chemical etch methods and dry plasma etch methods. Dry plasma etch methods are generally more common insofar as they typically provide vertical sidewalls (or nearly so) to the surface semiconductor layer 14′. Certain wet chemical etch methods that may have a crystallographic specificity may also be used.

FIG. 2 also shows a doped well 11 (i.e., a plate) located within the base semiconductor substrate 10 at a portion thereof over which is not located the surface semiconductor layer 14′. The doped well 11 may be formed using an ion implantation method while masking appropriate portions of the semiconductor structure that is illustrated within FIG. 2. The doped well 11 may include either an n dopant or a p dopant. The doped well 11 may have either the same or different doping in comparison with the base semiconductor substrate 10. Typically, the doped well 11 is comparatively heavily doped (i.e., either n+ or p+) and has a dopant concentration from about 5 e17 to about 5 e20 dopant atoms per cubic centimeter.

FIG. 3 shows an isolation region 16 located upon the buried dielectric layer 12 and covering the doped well 11.

The isolation region 16 may optionally be filled to reduce effects from topography during processing of the structure that is illustrated in FIG. 3. The fill may comprise a dielectric material selected from the same group of dielectric materials from which is comprised the buried dielectric layer 12. The group of dielectric materials includes but is not limited to oxides, nitrides and oxynitrides of silicon. Oxides, nitrides and oxynitrides of other elements are not excluded. The isolation region 16 and the buried dielectric layer 12 may comprise the same dielectric material or a different dielectric material. The dielectric material from which is comprised the isolation region 16 may also be formed using any of the same methods that are disclosed above and used with respect to forming the dielectric material from which is comprised the buried dielectric layer 12. Typically the isolation region 16 is formed using a blanket layer deposition and subsequent planarization method that uses the surface semiconductor layer 14′ as a planarizing stop layer. Thus, the isolation region 16 has a thickness largely similar to the thickness of the surface semiconductor layer 14′, which as disclosed above is from about 300 to about 3000 angstroms.

FIG. 4 shows an isolation region 16′ and a buried dielectric layer 12′ that result from patterning of the isolation region 16 and the buried dielectric layer 12 that are illustrated in FIG. 3. Bounded laterally by the isolation region 16′ and the buried dielectric layer 12′ are a first aperture A1 and a second aperture A2. The first aperture A1 and the second aperture A2 typically expose, but typically do not penetrate, the doped well 11. As is illustrated in FIG. 4, the first aperture A1 and the second aperture A2 are laterally bounded (i.e., sidewall bounded) by only dielectric materials from which are comprised the buried dielectric layer 12′ and the isolation region 16′.

The foregoing patterning of the buried dielectric layer 12 to form the buried dielectric layer 12′ and the isolation region 16 to form the isolation region 16′ may be effected using photolithographic and etch methods that are conventional in the semiconductor fabrication art. In accordance with disclosure above, plasma etch methods are typically used since plasma etch methods generally provide straight sidewalls to the first aperture A1 and the second aperture A2. Certain wet chemical etch methods may also be used.

FIG. 5 to FIG. 8 show four embodiments of an anti-fuse structure that results from further processing of the semiconductor structure whose schematic cross-sectional diagram is illustrated in FIG. 4.

FIG. 5 shows a first anti-fuse material layer 18a located at the bottom of the first aperture A1 but not the bottom of the second aperture A2. FIG. 5 also shows a first conductor stud layer 20a filling the first aperture A1 and contacting the first anti-fuse material layer 18a. FIG. 5 finally shows a second conductor stud layer 20b filling the second aperture A2 and contacting the doped well 11. Although the first conductor stud layer 20a and the second conductor stud layer 20b are designated separately, they may be formed in a single lithographic and deposition process step.

FIG. 6 shows a first anti-fuse material layer 18a located at the bottom of the first aperture A1 and a second anti-fuse material layer 18b located at the bottom of the second aperture A2. FIG. 6 also shows a first conductor stud layer 20a filling the first aperture A1 and contacting the first anti-fuse material layer 18a and a second conductor stud layer 20b filling the second aperture A2 and contacting the second anti-fuse material layer 18b.

FIG. 7 shows a first conductor stud layer 20a and a second conductor stud layer 20b filling, respectively, the first aperture A1 and the second aperture A2, with each of the first conductor stud layer 20a and the second conductor stud layer 20b contacting the doped well 11. FIG. 7 also shows a first anti-fuse material layer 18c located upon the first conductor stud layer 20a, but not upon the second conductor stud layer 20b. FIG. 7 finally shows a first conductor capping layer 24a contacting the first anti-fuse material layer 18a and a second conductor capping layer 24b contacting the second conductor stud layer 20b.

FIG. 8 shows a first conductor stud layer 20a and a second conductor stud layer 20b filling, respectively, the first aperture A1 and the second aperture A2, with each of the first conductor stud layer 20a and the second conductor stud layer 20b contacting the doped well 11. FIG. 8 also shows a first anti-fuse material layer 18c located upon the first conductor stud layer 20a, and a second anti-fuse material layer 18d located upon the second conductor stud layer 20b. FIG. 8 finally shows a first conductor capping layer 24a contacting the first anti-fuse material layer 18c and a second conductor capping layer 24b contacting the second anti-fuse material layer 18d.

FIG. 8 also shows a transistor T located upon the surface semiconductor layer 14′ Although not specifically illustrated, the same transistor T may also be located and formed upon the surface semiconductor layer 14′ within the other embodiments of the anti-fuse structure that are illustrated in FIG. 5 to FIG. 7. Within the context of the embodiment illustrated in FIG. 8, a gate dielectric 18e within the transistor T may in particular be formed simultaneously with the first anti-fuse material layer 18c and/or the second anti-fuse material layer 18d. Alternatively, the gate dielectric 18e may also be formed simultaneously with the first anti-fuse material layer 18a and/or the second anti-fuse material layer 18b that is illustrated in FIG. 5 or FIG. 6. In addition, a gate electrode 24c may be formed simultaneously with the first conductor capping layer 24a and the second conductor capping layer 24b that are also illustrated in FIG. 8 contacting the first anti-fuse material layer 18c and the second anti-fuse material layer 18d.

Further, the gate electrode 24c may under certain circumstances also comprise the same conductor material that comprises the conductor stud layers 20a and/or 20b, in particular when an anti-fuse material layer 18a or 18b at the bottom of the first aperture A1 and the second aperture A2 that are illustrated in FIG. 4 is identical to the gate dielectric 18e. Alternatively, the anti-fuse material layers 18a and 18b in general may also comprise a different dielectric material than the gate dielectric 18e. Thus, the foregoing options for compositions of: (1) the gate electrode 24c; (2) the conductor capping layers 24a and 24b; (3) the anti-fuse material layers 18a, 18b, 18c and 18d; (4) the gate dielectric 18e; and (5) the conductor stud layers 20a and 20b, may easily utilize existing mask levels and interconnect structures to save on additional cost.

Within each of the embodiments that are illustrated within FIG. 5, FIG. 6, FIG. 7 and FIG. 8, the anti-fuse material layers 18a, 18b, 18c and 18d, and the gate dielectric 18e may comprise either deposited anti-fuse/gate dielectric materials or thermally grown anti-fuse/gate dielectric materials. Desirably included in particular are generally higher dielectric constant gate dielectric materials that are disclosed in further detail below.

Thermally grown anti-fuse/gate dielectric materials derive from the same base material as: (1) the base semiconductor substrate 10 (at the location of the doped well 11 for anti-fuse material layers 18a and 18b); (2) the conductor stud layers 20a and 20b (at top surfaces thereof for anti-fuse material layers 18c and 18d); and (3) the surface semiconductor layer 14′ (for gate dielectric 18e). Thus, thermally grown anti-fuse/gate dielectric material layers are typically oxides or nitrides of base materials from which are comprised the semiconductor substrate 10, the conductor stud layers 20a and 20b or the surface semiconductor layer 14′. The base materials are disclosed in further detail above for the base semiconductor substrate 10 and the surface semiconductor layer 14′. Base materials are disclosed in further detail below for the conductor stud layers 20a and 20b.

Deposited anti-fuse/gate dielectric materials may comprise any of several dielectric materials from which may desirably be comprised the gate dielectric 18e. More particularly, the gate dielectric 18e may comprise a generally conventional gate dielectric material having a dielectric constant from about 4 to about 20, measured in vacuum. Non-limiting examples of such gate dielectric materials also include oxides, nitrides and oxynitrides of silicon, although oxides, nitrides and oxynitrides of other elements are not excluded. The gate dielectric 18e may alternatively comprise a generally higher dielectric constant deposited gate dielectric material having a dielectric constant from about 20 to at least about 100. Non-limiting examples of this type of gate dielectric material include titanium oxides, lanthanum oxides, barium-strontium titanates and lead-zirconate titanates.

Typically, the anti-fuse material layers 18a, 18b, 18c and 18d, and the gate dielectric 18e, comprise a thermal silicon oxide dielectric material that has a thickness from about 10 to about 50 angstroms.

The foregoing embodiments contemplate that the anti-fuse material layers 18a, 18b, 18c and 18d may have a generally low thickness of less than about 12 angstroms. Such a low thickness often provides for a tunneling current through any one of the foregoing anti-fuse material layers 18a, 18b, 18c or 18d prior to programming of an anti-fuse structure in accordance with the invention. The presence and magnitude of such a tunneling current may allow for a determination of whether an anti-fuse is programmed. The tunneling current may also be useful in determining other electrical properties of an anti-fuse structure in accordance with the embodiments.

The conductor stud layers 20a and 20b may be formed from any of several conductor stud materials. Non-limiting examples include certain metals, metal alloys, metal nitrides and metal silicides, as well as doped polysilicon (i.e., having a dopant concentration from about 1 e18 to about 1 e22 dopant atoms per cubic centimeter) and polycide (doped polysilicon/metal silicide stack) conductor materials. The conductor materials may be deposited using any of several methods that are appropriate to their materials of composition. Included are plating methods, chemical vapor deposition methods (including atomic layer chemical vapor deposition methods) and physical vapor deposition methods (including sputtering methods). Typically, each of the conductor stud layers 20a and 20b comprises a polysilicon conductor material having a dopant concentration from about 1 e17 to about 1 e22 dopant atoms per cubic centimeter.

The polysilicon material is typically formed using a chemical vapor deposition method that provides a blanket layer of polysilicon material that fills the first aperture A1 and the second aperture A2. The blanket layer of polysilicon material may then be planarized to provide the conductor stud layers 20a and 20b. Planarization methods may include, but are not limited to mechanical planarizing methods and chemical mechanical polish planarizing methods. An etch back method comprising a wet or a dry etch may also be used. Chemical mechanical polish planarizing methods are generally more common.

The gate electrode 24c and the conductor capping layers 24a and 24b may comprise any of several conductor materials similar to the conductor stud layers 20a and 20b. Also included are certain metals, metal alloys, metal silicides and metal nitrides, as well as doped polysilicon and polycide materials. Typically, the gate electrode 24c and the conductor capping layers 24a and 24b comprise a doped polysilicon conductor material that has a thickness from about 500 to about 2000 angstroms.

The foregoing embodiments contemplate that: (1) the doped well 11 and the conductor stud layers 20a and 20b (with reference to FIG. 5 and FIG. 6); or (2) the conductor stud layers 20a and 20b and the conductor capping layers 24a and 24b (with reference to FIG. 7 and FIG. 8) comprise doped polysilicon materials that may have either the same polarity or different polarities. When the above paired structures comprise polysilicon materials having different polarities, a diode results from fusing an anti-fuse material layer 18a, 18b, 18c or 18d. Characteristics of such a diode (i.e., forward biasing or reverse biasing) may be discerned by electrical properties of the diode. When the foregoing conductor stud layer 20a and 20b combinations with the doped well 11 and the conductor capping layers 24a and 24b have the same polarity, generally a doped resistor may be formed incident to fusing of an anti-fuse material layer 18a, 18b, 18c or 18d.

Also comprising the transistor T that is illustrated in FIG. 8 are a pair of spacers 26 and a pair of source/drain regions 28. The spacers 26 are located adjacent and adjoining sidewalls of the gate electrode 24c. The source/drain regions 28 are located within the surface semiconductor layer 14′ and separated by a channel beneath the gate electrode 24c.

The spacers 26 generally comprise a dielectric material, although spacers comprising conductor materials are also known. Dielectric spacer materials typically include oxides, nitrides and oxynitrides of silicon, although dielectric spacer materials that comprise oxides, nitrides and oxynitrides of other materials are also known. Typically, the spacers 26 comprise a laminate of dielectric materials that typically includes silicon oxide dielectric materials. The spacers 26 are typically formed using a blanket layer deposition and anisotropic etch back method.

The source/drain regions 28 are typically formed using a two-step ion implantation method. A first step within the two step ion implantation method uses the gate electrode 24a absent the spacers 26 as a mask to form extension region portions of the source/drain regions 28 into the surface semiconductor layer 14′. A second step within the two step ion implantation method uses the gate electrode 24c and the spacers 26 as a mask to form contact region portions of the source/drain regions 28 into the surface semiconductor layer 14′.

Although the transistor T is illustrated in FIG. 8 specifically as comprising the gate dielectric 18e, the gate electrode 24c, the spacers 26 and the source/drain regions 28, the transistor T within the embodiment that corresponds with FIG. 8 is intended for reference purposes. Thus, for clarity within the schematic diagrams that follow, the transistor T does not include designations of the foregoing individual components of the transistor T.

FIG. 5 to FIG. 8 show anti-fuse structures in accordance with four embodiments of the invention. The anti-fuse structures comprise the doped well 11 within the base semiconductor substrate 10. The doped well 11 serves as a conductor plate. The buried dielectric layer 12′ and the isolation region 16′ provide a first aperture A1 and a second aperture A2 that expose the doped well 11, but typically do not penetrate the doped well 11. Located within the first aperture A1 and the second aperture A2 are the corresponding first conductor stud layer 20a and the corresponding second conductor stud layer 20b. Located contacting the first conductor stud layer 20a is the first anti-fuse material layer 18a or 18c. Optionally located contacting the second conductor stud layer 20b is the second anti-fuse material layer 18b or 18d.

The anti-fuse structure in accordance with the embodiments illustrated in FIG. 5 to FIG. 8 may be fused by appropriate electrical potential applied to the conductor stud layers 20a and 20b (i.e., FIG. 5 and FIG. 6), or the conductor capping layers 24a and 24b (i.e., FIG. 7 and FIG. 8). When the optional second anti-fuse material layer 18b or 18d contacts the second conductor stud layer 20b (i.e., FIG. 6 and FIG. 8) an additional connection to the doped well 11 (e.g., possibly through the semiconductor substrate 10) may be needed to provide an operational anti-fuse structure.

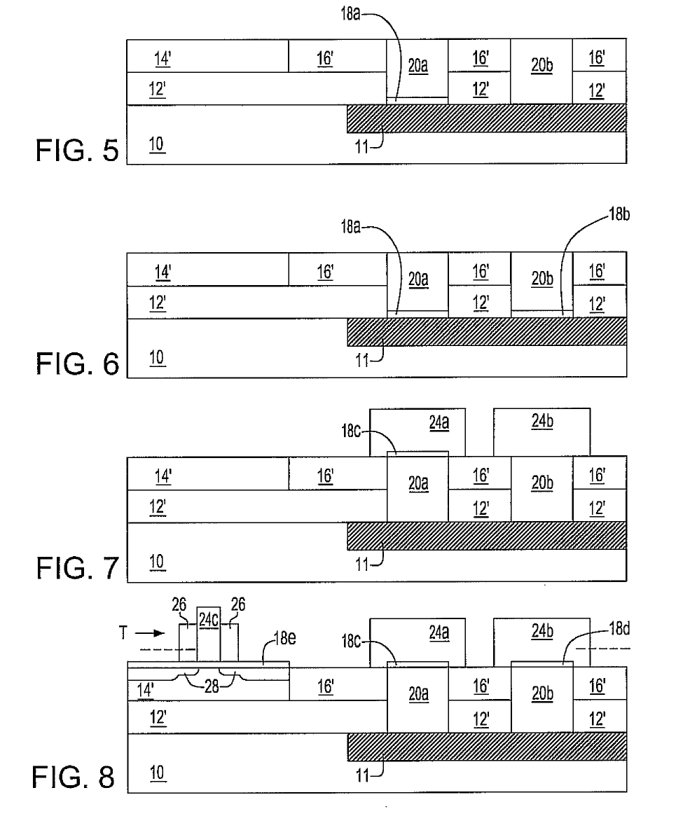

FIG. 9 to FIG. 12 show a series of schematic cross-sectional diagrams illustrating the four embodiments of the anti-fuse structure in accordance with FIG. 5 to FIG. 8 (now each also illustrating the transistor T), respectively, further fabricated with a guard ring structure 30 (FIG. 9 and FIG. 10) or a guard ring structure 30′ (FIG. 11 and FIG. 12). Also illustrated in FIG. 9 to FIG. 12 are dielectric layers 31 into which are embedded the guard ring structure 30 or the guard ring structure 30′.

The dielectric layers 31 may comprise materials and be formed using methods analogous to the buried dielectric layer 12 and the isolation region 16 that is illustrated in FIG. 3. In particular, the dielectric layers 31 may comprise dielectric materials such as but not limited to oxides, nitrides and oxynitrides of silicon. Oxides nitrides and oxynitrides of other elements are not excluded. The dielectric materials may be formed using methods including but not limited to thermal or plasma oxidation or nitridation methods, chemical vapor deposition methods and physical vapor deposition methods.

The guard ring structure 30 or the guard ring structure 30′ comprises a stack of patterned conductor stud layers and patterned conductor interconnect layers. By way of example within FIG. 9 and FIG. 10, component layers within the guard ring structure 30 may comprise: (1) a first contact stud 30a; (2) a second contact stud 30b; (3) a first interconnect layer 30c (corresponding with a first metal layer); (4) a first stud and interconnect layer 30d (corresponding with a second metal layer); and (5) a second stud and interconnect layer 30e (corresponding with a third metal layer). By way of example within FIG. 11 and FIG. 12, the guard ring structure 30′ may comprise: (1) a first contact stud 30a′; (2) the second contact stud 30b; (3) the first interconnect layer 30c (corresponding with the first metal layer); (4) the first stud and interconnect layer 30d (corresponding with the second metal layer); and (5) the second stud and interconnect layer 30e (corresponding with the third metal layer).

The patterned conductor stud layers and patterned conductor interconnect layers that comprise the guard ring structure 30 or the guard ring structure 30′ may comprise any of several conductor materials. Non-limiting examples include certain metals, metal nitrides and metal silicides. Particularly common are tungsten, copper and aluminum metals. Suitable barrier layers are typically included in conjunction with certain metal and dielectric material compositions in order to avoid undesirable interdiffusion of those metal and dielectric material compositions. The patterned conductor stud layers, patterned conductor interconnect layers and barrier layers that comprise the guard ring structure 30 or the guard ring structure 30′ may be formed using methods that are conventional in the semiconductor fabrication art. Non-limiting examples include plating methods, chemical vapor deposition methods and physical vapor deposition methods.

The anti-fuse structures in accordance with the embodiments of FIG. 5 to FIG. 8 provide value within the context of integration of the guard ring structures 30 and 30′ to provide the semiconductor structures of FIG. 9 to FIG. 12.

In particular, as an example, during processing of the semiconductor structures of FIG. 9 to FIG. 12, the anti-fuse structure that is illustrated in FIG. 5 to FIG. 8 provides that the guard ring structure 30 or 30′ may be electrically isolated from the base semiconductor substrate 10. Such electrical isolation allows the guard ring structure 30 or 30′ to electrically “float”. By electrically “floating,” the electrical potential of a guard ring structure (i.e., such as the guard ring structure 30 or 30′) and the circuitry on a substrate (i.e., such as a semiconductor-on-insulator substrate) are substantially the same during substrate processing. Thus, arcing of the substrate to the guard ring structure is avoided. Subsequent to all processing, the anti-fuse structures illustrated in FIG. 5 to FIG. 8 may be fused so that the guard ring structure 30 or 30′ is electrically connected to the base semiconductor substrate 10 at the location of the doped well 11. Thus, in accordance with the embodiments, guard ring structure 30 or 30′ may “float” at the same potential as semiconductor circuitry enclosed by the guard ring structure 30 or 30′ during processing of the semiconductor circuitry. The guard ring structure 30 or 30′ may then be connected to the base semiconductor substrate 10 by fusing of an anti-fuse structure illustrated in FIG. 5 to FIG. 8 after processing of semiconductor circuitry.

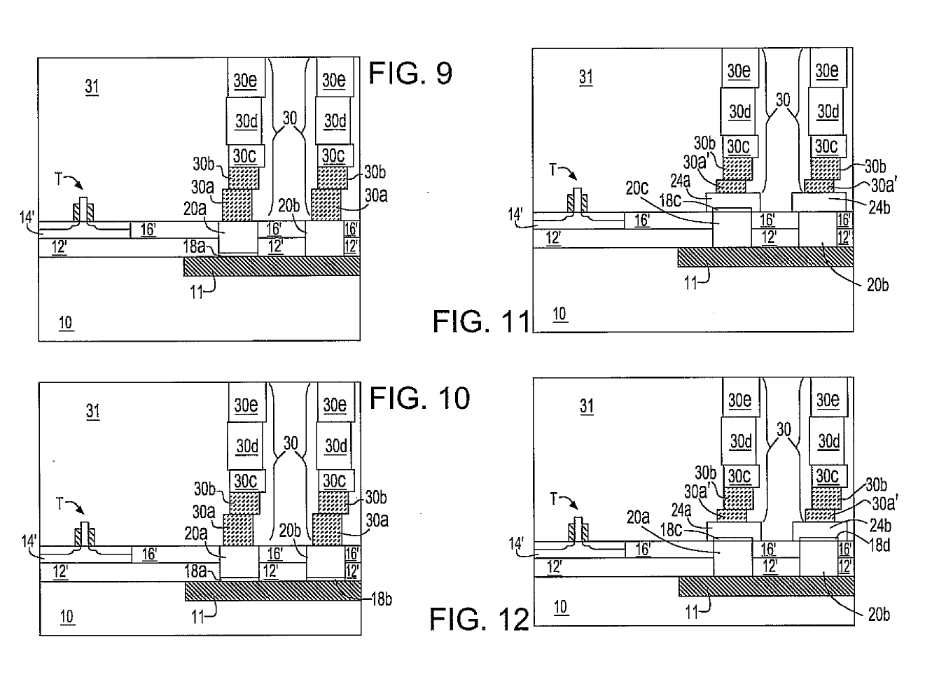

For illustrative purposes, FIG. 13 shows a schematic plan-view diagram of a guard ring structure in accordance with the foregoing embodiments of the invention. FIG. 13 shows the guard ring structure 30 that separates and encircles a circuitry region 40 of a semiconductor chip, with respect to a kerf region 42 of the semiconductor chip.

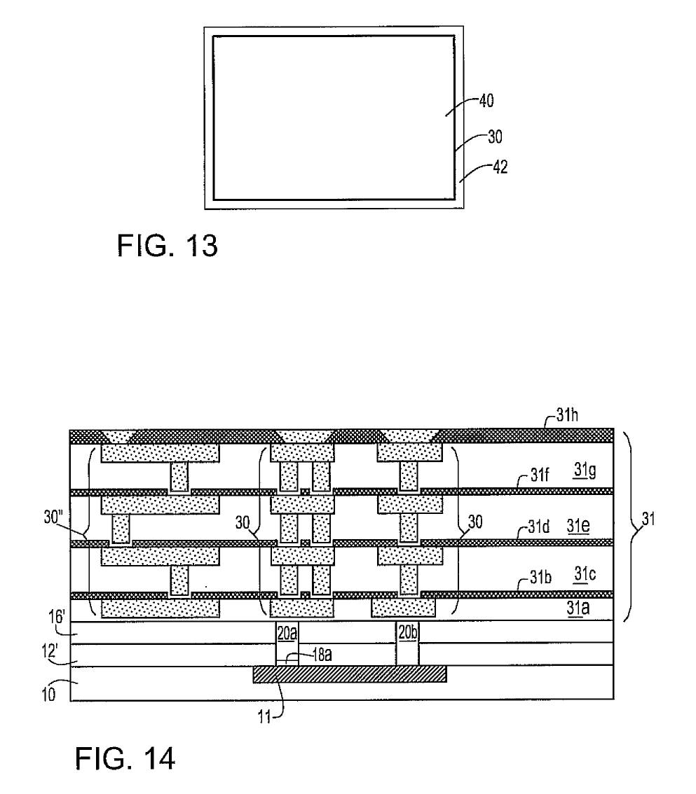

FIG. 14 shows a schematic cross-sectional diagram of a semiconductor structure correlating generally with the semiconductor structures that are illustrated in FIG. 9 to FIG. 12, but with greater detail for some of the components within the semiconductor structures. Like numbered structures are intended as representative of identical structures.

FIG. 14 shows the base semiconductor substrate 10 including the doped well 11, the buried dielectric layer 12′ located thereupon and the isolation region 16′ located further thereupon. FIG. 14 also shows the anti-fuse material layer 18a, as well as the conductor stud layers 20a and 20b, that penetrate through the isolation region 16′ and the buried dielectric layer 12′ to couple to the doped well 11.

FIG. 14 also shows different structures for the guard ring structures 30 that still comprise conductor interconnect and conductor stud layers. FIG. 14 further shows a plurality of active interconnect and stud layers 30″ that are spaced from the guard ring structures 30. FIG. 14 finally illustrates a plurality of sub-layers 31a, 31b, 31c, 31d, 31e, 31f, 31g and 31h that comprise the dielectric layer 31.

The preferred embodiments of the invention are illustrative of the invention rather than limiting of the invention. Revisions and modifications may be made to methods, materials structures and dimensions of an anti-fuse structure optionally integrated with a guard ring structure in accordance with the preferred embodiments, while still providing an anti-fuse structure optionally integrated with a guard ring structure in accordance with the invention, further in accordance with the accompanying claims.

What is claimed is:

1. A semiconductor structure comprising:
a semiconductor substrate including a doped well and a dielectric layer located covering the semiconductor substrate and the doped well;
at least a first aperture and a second aperture located within the dielectric layer, each of the first aperture and the second aperture exposing the doped well;
a first conductor layer located within the first aperture and a second conductor layer located within the second aperture; and
at least a first anti-fuse material layer contacting at least the first conductor layer.

2. The semiconductor structure of claim 1 wherein the first aperture and the second aperture are laterally bounded by a dielectric material only.

3. The semiconductor structure of claim 1 wherein the first anti-fuse material layer is located interposed between the doped well and the first conductor layer.

4. The semiconductor structure of claim 1 wherein the first anti-fuse material layer is located upon the first conductor layer.

5. The semiconductor structure of claim 1 further comprising a second anti-fuse material layer contacting the second conductor layer.

6. The semiconductor structure of claim 5 wherein the second anti-fuse material layer is located interposed between the doped well and the second conductor layer.

7. The semiconductor structure of claim 5 wherein the second anti-fuse material layer is located upon the second conductor layer.

8. The semiconductor structure of claim 1 wherein the first anti-fuse material layer separates the first conductor layer from an other conductor material of opposite polarity.

9. The semiconductor structure of claim 1 wherein the first anti-fuse material layer separates the first conductor layer from an other conductor material of the same polarity.

10. A semiconductor structure comprising:
a semiconductor substrate including a doped well and a dielectric layer located covering the semiconductor substrate and the doped well;
at least a first aperture and a second aperture located within the dielectric layer, each of the first aperture and the second aperture exposing the doped well;
a first conductor layer located within the first aperture and a second conductor layer located within the second aperture;
at least a first anti-fuse material layer contacting at least the first conductor layer; and
a guard ring structure electrically coupled to at least one of the first conductor layer and the second conductor layer.

11. The semiconductor structure of claim 10 wherein the guard ring structure is coupled to the first conductor layer.

12. The semiconductor structure of claim 10 wherein the guard ring structure is coupled to both the first conductor layer and the second conductor layer.

13. A method for fabricating a semiconductor structure comprising:
forming at least a first aperture and a second aperture located within a dielectric layer, each of the first aperture and the second aperture exposing a doped well within a semiconductor substrate located beneath the dielectric layer;
forming a first conductor layer located within the first aperture and a second conductor layer located within the second aperture; and
forming at least a first anti-fuse material layer contacting at least the first conductor layer.

14. The method of claim 13 further comprising forming additional circuitry and a guard ring structure over the semiconductor substrate, the guard ring structure being separated from the doped well by the first anti-fuse material layer.

15. The method of claim 14 further comprising fusing the first anti-fuse material layer after forming the additional circuitry and guard ring structure over the semiconductor substrate.

16. The method of claim 13 further comprising monitoring a tunneling current through the first anti-fuse material layer.

17. The method of claim 13 wherein the first anti-fuse material layer is located interposed between the doped well and the first conductor layer.

18. The method of claim 13 wherein the first anti-fuse material layer is located upon the first conductor layer.

19. The method of claim 13 further comprising forming a second anti-fuse material layer contacting the second conductor layer.

20. The method of claim 13 wherein the second anti-fuse material layer is located interposed between the doped well and the second conductor layer.
